(19) United States
(12) Patent Application Publication
(10) Pub. No.: US 2026/0031687 A1
(43) Pub. Date: Jan. 29, 2026

(54) IN-WHEEL MOTOR

(71) Applicants: HYUNDAI MOTOR COMPANY, SEOUL (KR); KIA CORPORATION, SEOUL (KR)

(72) Inventor: Sung Moo Joe, Hwaseong-si (KR)

(73) Assignees: HYUNDAI MOTOR COMPANY, SEOUL (KR); KIA CORPORATION, SEOUL (KR)

(21) Appl. No.: 19/051,963

(22) Filed: Feb. 12, 2025

(30) Foreign Application Priority Data
Jul. 29, 2024 (KR) 10-2024-0100345

(51) Int. Cl. H02K 11/33; B60K 7/00; B60K 11/02; H02K 7/102; H02K 9/22

(52) U.S. Cl. CPC H02K 11/33; B60K 7/0007; B60K 11/02; H02K 7/102; H02K 9/227; H02K 2211/03

(57) ABSTRACT

An in-wheel motor integrated with an inverter, which ensures body design degrees of freedom because a separate space for the inverter is not required, improves reliability because electrical connection between the in-wheel motor and the inverter is stabilized. The in-wheel motor comprises a motor cover having a wheel motor on a first side and formed with a through hole, and a power conversion device positioned on a second side of the motor cover, and comprising a power board and at least one power electric module. The power board and the power electric module are electrically connected by a first lead, and the power electric module and the wheel motor are electrically connected by a second lead passing through the through hole.

### CROSS REFERENCE TO RELATED APPLICATIONS

The present application claims priority to Korean Patent Application No. 10-2024-0100345, filed Jul. 29, 2024, the entire contents of which is incorporated herein for all purposes by this reference.

### BACKGROUND

### Technical Field

The disclosure relates to an in-wheel motor with an inverter.

### Description of the Related Art

The in-wheel motor is used in the means of transportation that uses electricity as a power source.

In the in-wheel motor, power is output from a motor placed inside a rim and directly transmitted to a wheel, thereby rotating the rim and the wheel.

Unlike the conventional means of transportation, the in-wheel motor does not use complex driving and power transmission devices such as an engine, a transmission, and a gear. Accordingly, the in-wheel motor may lighten the means of transportation and reduce energy loss occurring during power transmission.

The in-wheel motor includes a tire, a rim, a stator, a rotor, and a shaft.

Here, the tire is coupled surrounding the outer side of the rim, the stator and the rotor make up a motor assembly, and the motor assembly is provided on the inner side of the rim. The shaft is fastened to the center of the stator, and the stator receives power from outside. In this in-wheel motor, the stator receives power to rotate the rotor, and the rim rotates along with the rotor to rotate the tire.

Further, the in-wheel motor is provided with a brake device for a stopped state.

The brake device includes a disc and a caliper, and performs braking as the caliper presses the disc to which a driving shaft is connected.

Meanwhile, two in-wheel motors may be applied to each of front and rear wheels of a vehicle. Here, the in-wheel motor needs an inverter for high power when applied to an electric vehicle, and the inverter is installed in a separate space and electrically connected to each in-wheel motor.

Accordingly, a power electric (PE) system including the inverter is present in a body center portion of the electric vehicle. However, a space that should be secured for placing the PE system therein restricts a body design, and additional lines are required to electrically connect the PE system and the in-wheel motor.

The subject matters described above as the related art are merely intended to assist in the understanding of the background, and should not be considered as the prior art already known to those skilled in the art.

### SUMMARY

An aspect of the disclosure is to provide an in-wheel motor integrated with an inverter and stabilized in electrical connection with the inverter.

According to an embodiment of the disclosure, an in-wheel motor includes a motor cover provided with a wheel motor on a first side and formed with a through hole, and a power conversion device provided on a second side of the motor cover, and including a power board and at least one power electric module, wherein the power board and the power electric module are electrically connected by a first lead, and the power electric module and the wheel motor are electrically connected by a second lead passing through the through hole.

The through hole may be located inside the power electric module in the motor cover, the first lead may extend outward from the power electric module, and the second lead may be bent inward from the power electric module and extended to pass through the through hole.

The power conversion device may further include a cooling panel through which a refrigerant flows, and the power board and the power electric module are provided to be in contact with the cooling panel.

The power board may have a larger diameter than the cooling panel, a portion of the power board may be exposed in a radial direction, and the first lead may be electrically connected to the at least one power electric module and the exposed portion of the power board.

The power conversion device may include the power electric module provided on the first side of the cooling panel, and the power board provided on the second side of the cooling panel.

The power conversion device may include the power board provided on the first side of the cooling panel, and the power electric module provided on the second side of the cooling panel, the power board may include a communication hole, and the second lead may be electrically connected to the wheel motor through the communication hole and the through hole.

The power electric module may include at least one power module and at least one capacitor, the power module and the capacitor may be provided to be in contact with the cooling panel, and some of the second leads extending from the power module may be electrically connected to the capacitor.

The power module and the capacitor may be arranged radially on the cooling panel.

The power module and the capacitor may be alternately arranged on the cooling panel along a circumferential direction.

The through hole of the motor cover may be coated with an insulating material.

The power conversion device may further include an inverter cover coupled to the motor cover and forming an internal space, the inverter cover may be coupled to the second side of the motor cover while forming the internal space together with the motor cover, and the power board and the power electric module are provided in the internal space.

The motor cover may include a first central hole in a center thereof through which a driving shaft connected to the wheel motor passes, and at least one through hole around the first central hole along circumference thereof.

The inverter cover may include a second central hole formed matching the first central hole, and the power board may be shaped like a disc and include a third central hole matching the first central hole and the second central hole.

A border of the first central hole of the motor cover and a border of the second central hole of the inverter cover may be extended and connected in a direction facing each other, so that the internal space can be separated from the first central hole and the second central hole.

With the foregoing structure, the in-wheel motor does not need a separate space for the inverter because the inverter is integrated into the in-wheel motor, thereby ensuring body design degrees of freedom. Further, the electrical connection between the in-wheel motor and the inverter is stabilized, thereby improving reliability.

### BRIEF DESCRIPTION OF THE FIGURES

FIG. 1 is an exploded perspective view of an in-wheel motor according to an embodiment of the disclosure.

FIG. 2 is a view showing a motor cover and a power conversion device in the in-wheel motor shown in FIG. 1.

FIG. 3 is a view showing a power conversion device according to an embodiment of the disclosure.

FIG. 4 is a view showing a power conversion device according to another embodiment of the disclosure.

FIG. 5 is an exploded perspective view of the power conversion device according to the embodiment shown in FIG. 4.

FIG. 6 is a cross-sectional view of a motor cover and a power conversion device according to an embodiment of the disclosure.

### DETAILED DESCRIPTION

Hereinafter, embodiments of the disclosure will be described in detail with reference to the accompanying drawings, in which the same or similar elements are denoted by the same reference numerals even though they are depicted in different drawings and redundant descriptions thereof will be avoided.

Suffixes “module” and “unit” put after components in the following description are given in consideration of only ease of description and do not have meaning or functions discriminated from each other.

In terms of describing the embodiments of the disclosure, detailed descriptions of the related art will be omitted when they may make the subject matters of the embodiments of the disclosure rather unclear. In addition, the accompanying drawings are provided only for a better understanding of the embodiments of the disclosure and are not intended to limit technical ideas of the disclosure. Therefore, it should be understood that the accompanying drawings include all modifications, equivalents and substitutions within the scope and sprit of the disclosure.

Terms such as “first” and “second” may be used to describe various components, but the components should not be limited by the above terms. In addition, the above terms are used only for the purpose of distinguishing one component from another.

When it is described that one component is “connected” or “joined” to another component, it should be understood that the one component may be directly connected or joined to another component, but additional components may be present therebetween. However, when one component is described as being “directly connected,” or “directly coupled” to another component, it should be understood that additional components may be absent between the one component and another component.

Unless the context clearly dictates otherwise, singular forms include plural forms as well.

In the disclosure, it should be understood that term “include” or “have” indicates that a feature, a number, a step, an operation, an element, a part, or the combination thereof described in the embodiments is present, but does not preclude a possibility of presence or addition of one or more other features, numbers, steps, operations, elements, parts or combinations thereof, in advance.

Below, an in-wheel motor according to exemplary embodiments of the disclosure will be described with reference to the accompanying drawings.

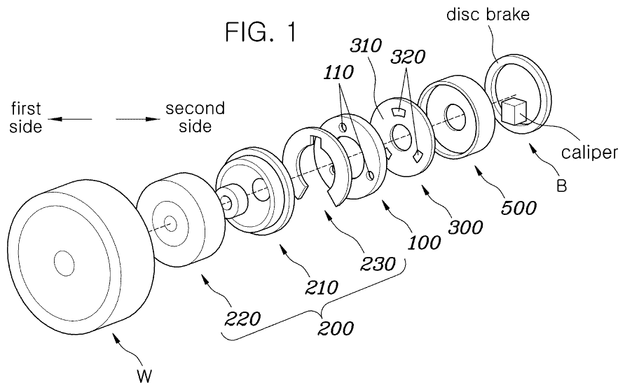

As shown in FIGS. 1 to 3, the in-wheel motor according to the disclosure includes a motor cover 100 provided with a wheel motor 200 on a first side and formed with a through hole 110; and a power conversion device 300 provided on a second side of the motor cover 100, and including a power board 310 and at least one power electric module 320, in which the power board 310 and the power electric module 320 are electrically connected by a first lead 330, and the power electric module 320 and the wheel motor 200 are electrically connected by a second lead 340 passing through the through hole 110.

The in-wheel motor according to an embodiment of the disclosure couples with a housing together with the motor cover 100 to form an outer appearance, and is mounted to the rim and inner side of a wheel. Here, the housing may serve as a rotor cover of the wheel motor 200.

The motor cover 100 is provided for coupling the wheel motor 200 to a driving wheel W of a vehicle.

The wheel motor 200 may include a stator 210, a rotor 220, and a motor control substrate 230, in which the stator 210 may be coupled and secured to the motor cover 100, and the rotor 220 may be coupled to the driving wheel W. Here, the rotor 220 may include a permanent magnet inside the rotor cover, and thus the wheel motor 200 may be configured as a brushless direct current (BLDC) electric motor. The detailed structure of the wheel motor 200 is not limited to the foregoing description, and various motor structures may be applied thereto.

Further, the wheel motor 200 may further include a brake device B. For example, the brake device B may be a drum brake type or a disc brake type. The brake device B may be connected to the driving wheel W and may generate braking force by pressing a drum or disc.

According to the disclosure, the wheel motor 200 is provided on the first side of the motor cover 100, and the power conversion device 300 is provided on the second side of the motor cover 100. The power conversion device 300 applies electric current to the stator 210 of the wheel motor 200, thereby generating a rotational force in the rotor 220 of the wheel motor 200.

The power conversion device 300 may include the power board 310 and at least one power electric module 320.

In other words, the power conversion device 300 may be configured as an inverter to convert direct current (DC) power into alternating current (AC) power when driving the wheel motor 200.

The power board 310 may include a control board 311 and a gate board 312, and the power electric module 320 may include a power module 321 and a capacitor 322.

Here, the power module 321 is provided with one or multiple semiconductor chips to form a current flow path by switching operations and perform power conversion, and the capacitor 322 is configured to have electrostatic capacity and stabilize a circuit.

The power conversion device 300 may be configured as various types of inverters depending on the number of power modules 321 and capacitors 322 and circuit formation.

In particular, according to the disclosure, there is provided an electrical connection structure between the wheel motor 200 provided on the first side of the motor cover 100 and the power conversion device 300 is provided on the second side of the motor cover 100.

To this end, at least one through hole 110 may be formed in the motor cover 100, and the second lead 340 extending from the power electric module 320 is bent passing through the through hole 110 and electrically connected to the wheel motor 200.

In other words, the power electric module 320 and the power board 310 are electrically connected by the first lead 330 on the second side of the motor cover 100 to transmit and receive switching signals, and the second lead 340 extending from the power electric module 320 passes through the through hole 110 of the motor cover 100 and is electrically connected to the wheel motor 200, thereby supplying power to the wheel motor 200. Here, the first lead 330 may be a signal lead, and the second lead 340 may be a power lead.

Further, the through hole 110 of the motor cover 100 may be coated with an insulating material. The insulating material may include epoxy, and various insulating materials other than the epoxy may be used. As the through hole 110 is coated with the insulating material, electrical leakage and power loss caused by the second lead 340 passing through the through hole 110 and being in contact with the motor cover 100 may be prevented.

In this way, according to the disclosure, the wheel motor 200 and the power conversion device 300 may be integrated into the motor cover 100, and thus a space for placing the power conversion device 300 therein is not separately required, thereby ensuring body design degrees of freedom.

In more detail, according to the disclosure, the through hole 110 may be located inside the power electric module 320 in the motor cover 100, the first lead 330 may extend outward from the power electric module 320, and the second lead 340 may be bent inward from the power electric module 320 and extended to pass through the through hole 110.

The stator 210 and the rotor 220 making up the wheel motor 200 are formed in a circle for rotational movement, and the inner side of the motor cover 100 covering the wheel motor 200 may also be formed in a circle. Thus, the power board 310 of the power conversion device 300 may also be formed in a disc shape to be installed in the motor cover 100.

As the power board 310 and the power electric module 320 are electrically connected on the second side of the motor cover 100, the first lead 330 may extend outwards to connect the power board 310 and the power electric module 320 without interfering with the other parts.

Meanwhile, the motor cover 100 may be pierced in the center for connection between the wheel motor 200 on the first side and the brake device B on the second side. In this way, the driving shaft S for connecting the wheel motor 200 and the brake device B may penetrate the center of the motor cover 100, and thus there is a space for the penetration in the center.

Accordingly, the through holes 110 may be located close to the center on the inner side of the motor cover 100. To electrically connect the power electric module 320 and the wheel motor 200 from the second side of the motor cover 100 to the first side of the motor cover 100, the second lead 340 may extend inward from the power electric module 320 and be bent to pass through the through hole 110 and electrically connected to the wheel motor 200.

The first lead 330 and the second lead 340 are not limited to the foregoing structures. However, both the first lead 330 and the second lead 340 may be configured to extend inward or outward from the power electric module 320. Alternatively, the first lead 330 may be configured to extend inward, and the second lead 340 may be configured to extend outward. When both the first lead 330 and the second lead 340 are extended inward or outward, the leads may interfere with each other and a space for their installation may increase. The closer the electrical connection structure of the wheel motor 200 is to the center of the motor cover 100, the easier it is to simplify the electrical connection structure. Therefore, the first lead 330 from the power electric module 320 is configured to extend outward, and the second lead 340 from the power electric module 320 is configured to extend inward.

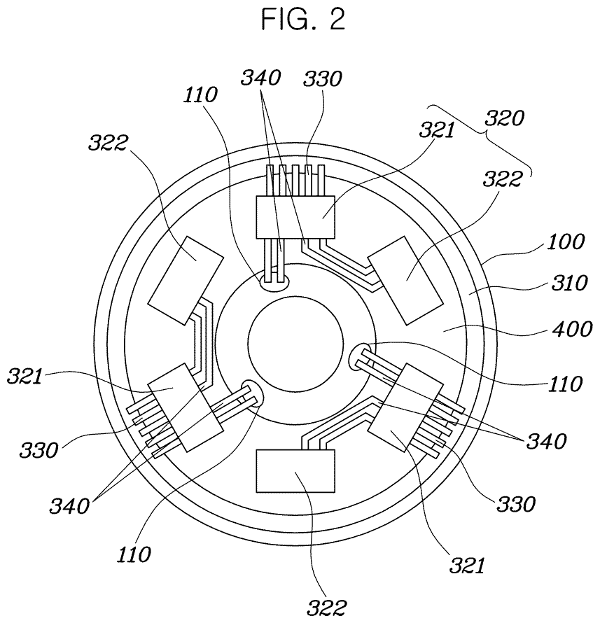

Meanwhile, as shown in FIG. 2, the power conversion device 300 may further include a cooling panel 400 through which a refrigerant flows, and the power board 310 and the power electric module 320 may be in contact with the cooling panel 400.

The cooling panel 400 may be provided as an air-cooled type or a water-cooled type. When the cooling panel 400 is the air-cooled type, a driving wind or an air flow generated due to the rotation of the driving shaft S connected to the rotor 220 may be used. When the cooling panel 400 is the water-cooled type, the circulation of the refrigerant connected to a cooling system may be used to perform the cooling.

Here, either the air-cooled type or the water-cooled type, or a combination of the air-cooled type and the water-cooled type may be used for the cooling panel 400. Besides, various cooling structures may be applied to the cooling panel 400, and detailed descriptions thereof will be omitted.

Because the power board 310 and the power electric module 320 are in contact with the cooling panel 400, the power board 310 and the power electric module 320 exchange heat with the cooling panel 400, thereby managing the temperature.

Meanwhile, the power board 310 has a larger diameter than the cooling panel 400, and a portion of the power board 310 is exposed in a radial direction. Thus, the first lead 330 may be electrically connected to at least one power electric module 320 and the exposed portion of the power board 310.

According to the disclosure, the power board 310 may be shaped like a disc, and the cooling panel 400 may also be shaped like a disc corresponding to the shape of the power board 310. Here, the shape and area of the cooling panel 400 may designed so that the power electric module 320 including the power module 321 and the capacitor 322 can be mounted to the cooling panel 400 in order to cool the power module 321 and the capacitor 322 which actually generate heat.

In addition, the power module 321 in the power electric module 320 needs to be electrically connected to the power board 310 and the wheel motor 200 by the first lead 330 and the second lead 340. In particular, the first lead 330 is configured to be connected to the power board 310 on the second side of the motor cover 100. Here, when the diameter of the power board 310 is larger than the diameter of the cooling panel 400, the first lead 330 needs to extend from the power module 321 toward the outside of the cooling panel 400 and be then connected to the power board 310, thereby complicating the connection structure of the first lead 330 and requiring a space to be secured for the first lead 330.

Therefore, the power board 310 is formed to have a larger diameter than the cooling panel 400, so that a portion of the power board 310 can be exposed to the outside of the cooling panel 400, and the first lead 330 can be connected through the exposed portion of the power board 310, thereby simplifying the electrical connection structure between the power electric module 320 and the power board 310.

Meanwhile, the power board 310, the power electric module 320 and the cooling panel 400 may be variously arranged in the power conversion device 300 according to embodiments.

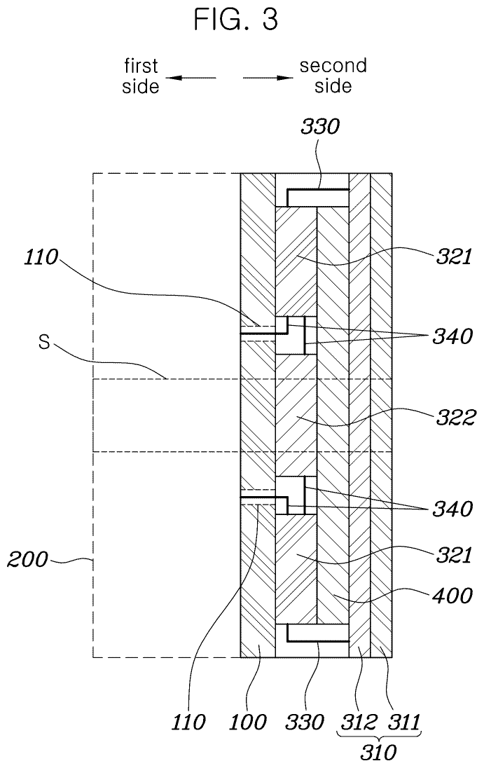

According to an embodiment, as shown in FIG. 3, the power conversion device 300 is provided with the power electric module 320 on the first side of the cooling panel 400 and the power board 310 on the second side of the cooling panel 400.

In other words, the power electric module 320 is placed on the first side of the cooling panel 400 and the power board 310 is placed on the second side of the cooling panel 400, so that the power electric module 320 can be adjacent to the motor cover 100, thereby reducing the length of the second lead 340 for the connection between the power electric module 320 and the wheel motor 200.

Further, the cooling of the power electric module 320, including the power module 321 and the capacitor 322, and the cooling of the power board 310 are simultaneously performed on both sides of the cooling panel 400, thereby ensuring a cooling efficiency and being advantageous in terms of packaging.

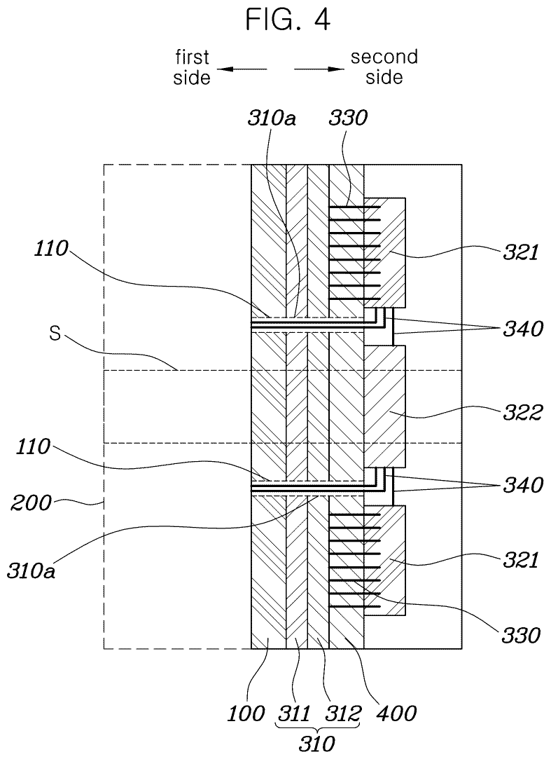

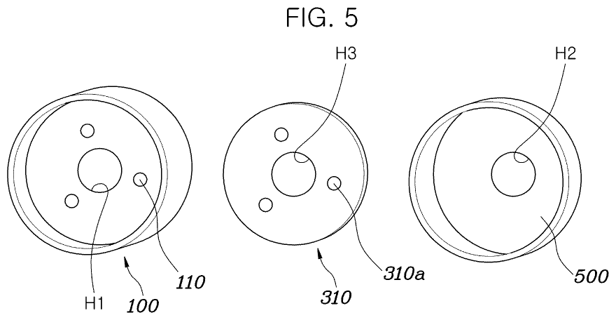

According to an alternative embodiment, as shown in FIGS. 4 and 5, the power conversion device 300 is provided with the power board 310 on the first side of the cooling panel 400, and the power electric module 320 on the second side of the cooling panel 400, and the power board 310 is formed with a communication hole 310a so that the second lead 340 can be electrically connected to the wheel motor 200 through the communication hole 310a and the through hole 110.

In other words, the power board 310 may be placed on the first side of the cooling panel 400, and the power electric module 320 may be placed on the second side of the cooling panel 400. To this end, the power board 310 may be formed with the communication hole 310a matching the through hole 110, and the second lead 340 extending from the power electric module 320 may be electrically connected to the wheel motor 200 while passing through the communication hole 310a and the through hole 110. Additionally, the cooling panel 400 may be also formed with a hole matching the through hole 110 and the communication hole 310a may be formed in the cooling panel 400, thereby allowing the second lead 340 to pass therethrough. In the cooling panel 400, a portion where the hole is formed is sealed, and thus the refrigerant flowing therein is not discharged through the hole.

Accordingly, a current circuit may be patterned on the power board 310 excluding the communication hole 310a, and the insulating material such as epoxy may be applied to the communication hole 310a of the power board 310 and the second lead 340.

Further, the cooling of the power electric module 320 including the power module 321 and the capacitor 322, and the cooling of the power board 310 are simultaneously performed on both sides of the cooling panel 400, thereby ensuring a cooling efficiency.

Meanwhile, some of the second leads 340 extending from the power module 321 may be electrically connected to the capacitor 322.

Referring to FIG. 2, the power module 321 in the power electric module 320 is electrically connected to the capacitor 322 via the second lead 340. In other words, some of the second leads 340 extending from the power module 321 are electrically connected to the wheel motor 200 while passing through the through hole 110 of the motor cover 100, and some are electrically connected to the capacitor 322. Here, the power module 321 and the capacitor 322 are arranged to be in contact with the same surface of the cooling panel 400, and thus the second lead 340 to be connected to the capacitor 322 extends in an inward direction of the power module 321 or in a circumferential direction of the power board 310.

For example, as shown in FIG. 2, the second leads 340 extend inward from the power module 321, and each second lead 340 may be connected to the capacitor 322 or bent to pass through the through hole 110.

Meanwhile, the power modules 321 and the capacitors 322 may be arranged radially on the cooling panel 400.

Further, the power module 321 and the capacitor 322 may be arranged on the cooling panel 400 alternately along the circumferential direction.

In other words, according to the disclosure, the cooling panel 400 may be shaped like a disc corresponding to the shape of the power board 310. Here, a plurality of power modules 321 and capacitors 322 making up the power electric module 320 are arranged radially on the cooling panel 400, thereby optimizing the arrangement of the power module 321 and the capacitor 322 within a limited area of the cooling panel 400.

Further, the power module 321 and the capacitor 322 are alternately arranged along the circumferential direction of the cooling panel 400, thereby reducing the extension length of the second lead 340 that electrically connects the power module 321 and the capacitor 322, and simplifying the structure of the second lead 340 for each connection between the power modules 321 and the capacitor 322.

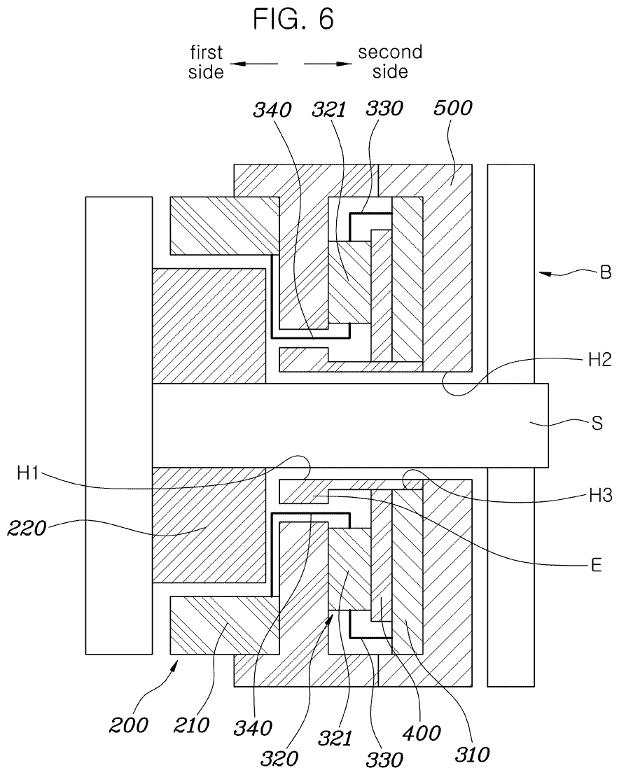

Meanwhile, as shown in FIGS. 1 and 6, the power conversion device 300 may further include an inverter cover 500 coupled to the motor cover 100 and forming an internal space.

The inverter cover 500 may be coupled to the second side of the motor cover 100 while forming the internal space together with the motor cover 100, and the power board 310 and the power electric module 320 may be provided in the internal space.

The motor cover 100 forms a space for the wheel motor 200 on the first side, and a space for the power conversion device 300 on the second side. The rotor cover for covering the wheel motor 200 may be provided on the first side of the motor cover 100. The rotor cover may be provided with a rotor 220 made of a permanent magnet on the inner side, and have a structure for coupling and rotating with the driving wheel W.

The inverter cover 500 is coupled to the second side of the motor cover 100 and, together with the motor cover 100, forms an internal space. The internal space may allow the power board 310 and the power electric module 320 to be placed therein, and may be configured to be airtight inside and outside.

Here, the motor cover 100 is formed with a first central hole H1 in the center thereof through which the driving shaft S connected to the wheel motor 200 passes, and at least one through hole 110 around the first central hole H1 along the circumference thereof.

The driving shaft S is provided to connect the wheel motor 200 and the brake device B, and connected to the wheel motor 200 and the brake device B while passing through the first central hole H1 of the motor cover 100.

The first central hole H1 of the wheel motor 200 may be formed in the central portion of the motor cover 100, and the at least one through hole 110 may be located around the first central hole H1 while being spaced apart from the first central hole H1. In this way, the through hole 110 is separated and spaced apart from the first central hole H1, so that the second lead 340 can be located in the internal space between the motor cover 100 and the inverter cover 500 and thus prevented from contamination and damage. In other words, the first central hole H1 of the wheel motor 200, through which the driving shaft S passes, is exposed to the outside, but the through hole 110 is separated from the first central hole H1 and located within a sealed internal space, thereby being insulated and prevented from contamination and damage.

Meanwhile, the inverter cover 500 may be formed with a second central hole H2 matching the first central hole H1, and the power board 310 may be shaped like a disc and formed with a third central hole H3 matching the first central hole H1 and the second central hole H2.

In this way, the first central hole H1 of the motor cover 100, the second central hole H2 of the inverter cover 500, and the third central hole H3 of the power board 310 are formed matching and communicating with each other, so that the driving shaft S can pass through the central holes.

Thus, according to the disclosure, the wheel motor 200 and the power conversion device 300 provided on the first and second sides of the motor cover 100 are integrated, and the driving shaft S connected to the wheel motor 200 is connected to the brake device B while penetrating the motor cover 100, the inverter cover 500 and the power board 310, thereby achieving an integrated in-wheel motor 200 having even a braking function.

Meanwhile, the border of the first central hole H1 of the motor cover 100 and the border of the second central hole H2 of the inverter cover 500 are extended and connected in a direction facing each other, so that the internal space can be separated from the first central hole H1 and the second central hole H2.

Referring to FIG. 6, the motor cover 100 and the inverter cover 500 may be connected to each other via the extension end portion E. The extension end E may be formed in a cylindrical shape and extend from either the first central hole H1 of the motor cover 100 or the second central hole H2 of the inverter cover 500, or from both of them to match each other.

In this way, the extension end portion E allows the first central hole H1 of the motor cover 100 and the second central hole H2 of the inverter cover 500 to form a passage, so that the driving shaft S can pass through the inside of the extension end portion E, and the internal space between the motor cover 100 and the inverter cover 500, i.e., outside the extension end portion E may be separated from the central holes.

As a result, the internal space between the motor cover 100 and the inverter cover 500 is separated from each central hole, thereby protecting the power board 310 and the power electric module 320.

With the foregoing structure, the in-wheel motor does not need a separate space for the inverter because the inverter is integrated into the in-wheel motor, thereby ensuring body design degrees of freedom. Further, the electrical connection between the in-wheel motor 200 and the inverter is stabilized, thereby improving reliability.

Although specific embodiments of the disclosure have been illustrated and described, it will be obvious to a person having ordinary knowledge in the art that various modifications and changes can be made in the disclosure without departing from the technical scope of the disclosure.

1. An in-wheel motor comprising:
a motor cover having a wheel motor on a first side and formed with a through hole; and
a power conversion device positioned on a second side of the motor cover, and comprising a power board and at least one power electric module;
wherein the power board and the power electric module are electrically connected by a first lead, and the power electric module and the wheel motor are electrically connected by a second lead passing through the through hole.

2. The in-wheel motor of claim 1, wherein the through hole is located inside the power electric module in the motor cover, and wherein the first lead extends outward from the power electric module, and the second lead is bent inward from the power electric module and extended to pass through the through hole.

3. The in-wheel motor of claim 1, wherein the power conversion device further comprises a cooling panel through which a refrigerant flows, and the power board and the power electric module are in contact with the cooling panel.

4. The in-wheel motor of claim 3, wherein the power board has a larger diameter than the cooling panel, a portion of the power board is exposed in a radial direction, and the first lead is electrically connected to the at least one power electric module and the exposed portion of the power board.

5. The in-wheel motor of claim 3, wherein the power conversion device comprises the power electric module positioned on a first side of the cooling panel, and the power board positioned on a second side of the cooling panel.

6. The in-wheel motor of claim 3, wherein the power conversion device comprises the power board positioned on a first side of the cooling panel, and the power electric module positioned on a second side of the cooling panel, the power board comprises a communication hole, and the second lead is electrically connected to the wheel motor through the communication hole and the through hole.

7. The in-wheel motor of claim 3, wherein the power electric module comprises at least one power module and at least one capacitor, the power module and the capacitor are in contact with the cooling panel, and some of the second leads extending from the power module are electrically connected to the capacitor.

8. The in-wheel motor of claim 7, wherein the power module and the capacitor are arranged radially on the cooling panel.

9. The in-wheel motor of claim 7, wherein the power module and the capacitor are alternately arranged on the cooling panel along a circumferential direction.

10. The in-wheel motor of claim 1, wherein the through hole of the motor cover is coated with an insulating material.

11. The in-wheel motor of claim 1, wherein the power conversion device further comprises an inverter cover coupled to the motor cover and forming an internal space, wherein the inverter cover is coupled to the second side of the motor cover while forming the internal space together with the motor cover, and the power board and the power electric module are positioned in the internal space.

12. The in-wheel motor of claim 11, wherein the motor cover comprises a first central hole in a center through which a driving shaft connected to the wheel motor passes, and at least one through hole around the first central hole along a circumference of the first central hole.

13. The in-wheel motor of claim 12, wherein the inverter cover comprises a second central hole identical to the first central hole, and the power board is shaped like a disc and comprises a third central hole identical to the first central hole and the second central hole.

14. The in-wheel motor of claim 13, wherein a border of the first central hole of the motor cover and a border of the second central hole of the inverter cover are extended and connected in a direction facing each other, so that the internal space can be separated from the first central hole and the second central hole.
